(19) United States
(12) Patent Application Publication
(10) Pub. No.: US 2015/0031195 A1
(43) Pub. Date: Jan. 29, 2015

(54) Method of Fabricating a Semiconductor Device

(71) Applicant: Samsung Electronics Co., Ltd., Suwon-si (KR)

(72) Inventors: Eun Tae Kim, Hwaseong-si (KR); Jihoon Kim, Gwacheon-si (KR); Heesook Park, Hwaseong-si (KR); Jin Ho Oh, Seongnam-si (KR); Jongmyeong Lee, Seongnam-si (KR)

(21) Appl. No.: 14/297,734

(22) Filed: Jun. 6, 2014

(30) Foreign Application Priority Data
Jul. 24, 2013 (KR) 10-2013-0087554

(51) Int. Cl. H01L 29/49; H01L 21/28

(52) U.S. Cl. CPC H01L 29/4958; H01L 21/28194
USPC 438/589

(57) ABSTRACT

A method of fabricating a semiconductor device may include conformally forming a gate insulating layer on a substrate having a recess, conformally forming a barrier layer containing fluorine-free tungsten nitride on the substrate with the gate insulating layer using an atomic layer deposition process, and forming a gate electrode on the barrier layer to fill at least a portion of the recess.

### CROSS-REFERENCE TO RELATED APPLICATIONS

This U.S. non-provisional patent application claims priority under 35 U.S.C. §119 to Korean Patent Application No. 10-2013-0087554, filed on Jul. 24, 2013, in the Korean Intellectual Property Office, the entire contents of which are hereby incorporated by reference.

### BACKGROUND

Due to their small-size, multifunctionality, and/or low-cost characteristics, semiconductor devices are considered important elements in the electronic industry. The semiconductor devices can be generally classified into a memory device for storing data, a logic device for processing data, and a hybrid device capable of performing various memory storage and data processing functions simultaneously.

Higher integration of semiconductor devices helps to satisfy consumer demands for electronic devices with a fast speed. However, owing to a decreasing process margin in a photolithography process, it is becoming harder to realize the highly-integrated semiconductor devices. To overcome such a limitation, a variety of studies have been recently done on new technology for increasing an integration density of the semiconductor device.

### SUMMARY

Example embodiments of the inventive concept provide a method of fabricating a highly-integrated semiconductor device.

Example embodiments of the inventive concept relate to a method of fabricating a semiconductor device, and in particular, to a buried channel array transistor (BCAT) and a method of fabricating the same.

According to example embodiments of the inventive concept, a method of fabricating a semiconductor device may include conformally forming a gate insulating layer on a substrate with a recess, conformally forming a barrier layer containing fluorine-free tungsten nitride on the substrate with the gate insulating layer using an atomic layer deposition process, and forming a gate electrode on the barrier layer to fill at least a portion of the recess.

In example embodiments, the forming of the barrier layer may include loading the substrate with the gate insulating layer into a process chamber, supplying a first precursor containing tungsten into the process chamber, and supplying a second, precursor containing nitrogen into the process chamber.

In example embodiments, the first precursor contains bis(tert-butylimido)-bis-(dimethylamido)tungsten(VI) (BTBMW) or methylcyclopentadienyl-dicarbonylnitrosyl-tungsten (MDNOW).

In example embodiments, the second precursor contains ammonia (NH₃).

In example embodiments, the method may further include firstly purging the process chamber, after the supplying of the first precursor, and secondly purging the process chamber, after the supplying of the second precursor.

In example embodiments, the atomic layer deposition process may be performed using a plasma-enhanced atomic layer deposition process.

In example embodiments, the plasma-enhanced atomic layer deposition process may include loading the substrate with the gate insulating layer in a process chamber, supplying a precursor of methylcyclopentadienyl-dicarbonylnitrosyl-tungsten (MDNOW) into the process chamber, firstly purging the process chamber, supplying a precursor of ammonia (NH₃) into the process chamber, in which plasma may be produced, secondly purging the process chamber, supplying a precursor of hydrogen (H₂) into the process chamber, in which plasma may be produced, and thirdly purging the process chamber.

In example embodiments, the plasma-enhanced atomic layer deposition process may include loading the substrate with the gate insulating layer in a process chamber, supplying a precursor of methylcyclopentadienyl-dicarbonylnitrosyl-tungsten (MDNOW) into the process chamber, firstly purging the process chamber, supplying a precursor of hydrogen (H₂) into the process chamber, in which plasma may be produced, secondly purging the process chamber, supplying a precursor of ammonia (NH₃) into the process chamber, in which plasma may be produced, and thirdly purging the process chamber.

In example embodiments, the plasma-enhanced atomic layer deposition process may be performed under plasma with power ranging from about 250 W to about 350 W, at a temperature ranging from about 100° C. to about 200° C.

In example embodiments, the atomic layer deposition process may be performed using a thermal atomic layer deposition (thermal ALD) process.

In example embodiments, the thermal atomic layer deposition process may include loading the substrate with the gate insulating layer in a process chamber heated to a temperature ranging from 300° C. to 500° C., supplying a precursor of bis(tert-butylimido)-bis-(dimethylamido)tungsten (VI) (BTBMW) into the process chamber, firstly purging the process chamber, supplying a precursor of ammonia (NH₃) into the process chamber, and secondly purging the process chamber.

In example embodiments, the gate electrode may be formed to contain tungsten.

In example embodiments, the forming of the gate electrode may include conformally forming a nucleation layer on the barrier layer, forming a tungsten layer to fill the recess provided with the nucleation layer using a chemical vapor deposition process, and etching the tungsten layer, the nucleation layer, and the barrier layer to expose the gate insulating layer through an upper side surface of the recess.

In example embodiments, the forming of the nucleation layer may include loading the substrate provided with the barrier layer in a process chamber, supplying a first precursor containing tungsten into the process chamber, and supplying a second precursor containing boron into the process chamber.

In example embodiments, the first precursor contains WF₆ and the second precursor contains B₂H₆.

According to other example embodiments of the inventive concept, a method of fabricating a semiconductor device includes: conformally forming a gate insulating layer on a substrate having a recess; conformally forming a barrier layer containing fluorine-free tungsten nitride on the substrate with the gate insulating layer using an atomic layer deposition process; and forming a gate electrode on the barrier layer to fill at least a portion of the recess. Forming the barrier layer includes: loading the substrate with the gate insulating layer into a process chamber; supplying a first precursor containing tungsten into the process chamber; then purging the process chamber a first time; then supplying a second precursor containing nitrogen into the process chamber; and then purging the process chamber a second time.

The first precursor may contain bis(tert-butylimido)-bis-(dimethylamido)tungsten(VI) (BTBMW) or methylcyclopentadienyl-dicarbonylnitrosyl-tungsten (MDNOW). The second precursor may contain ammonia (NH₃).

According to other example embodiments of the inventive concept, a method of fabricating a semiconductor device includes: conformally forming a gate insulating layer on a substrate having a recess; conformally forming a barrier layer containing fluorine-free tungsten nitride on the substrate with the gate insulating layer using a plasma-enhanced atomic layer deposition process; and forming a gate electrode on the barrier layer to fill at least a portion of the recess. The plasma-enhanced atomic layer deposition process is performed under plasma with power ranging from about 250 W to about 350 W and at a temperature ranging from about 100° C. to about 200° C.

In example embodiments, the plasma-enhanced atomic layer deposition process includes: loading the substrate with the gate insulating layer in a process chamber; then supplying a precursor of methylcyclopentadienyl-dicarbonylnitrosyl-tungsten (MDNOW) into the process chamber; then purging the process chamber a first time; then supplying a precursor of one of ammonia (NH₃) and hydrogen (H₂) into the process chamber; then purging the process chamber a second time; then supplying a precursor of the other one of ammonia (NH₃) and hydrogen (H₂) into the process chamber; and then purging the process chamber a third time.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIGS. 1A through 10B are plan and sectional views illustrating a semiconductor device according to example embodiments of the inventive concept.

FIG. 11A is a process cycle illustrating a process of forming a barrier layer according to example embodiments of the inventive concept.

FIG. 11B is a process cycle illustrating a process of forming a barrier layer according to other example embodiments of the inventive concept.

FIG. 12A is a graph showing a relationship between resistance and thickness of gate electrodes that were formed by conventional methods and methods according to example embodiments of the inventive concept.

FIG. 12B is a graph showing a relationship between resistance and design rule of gate electrodes that were formed by the conventional methods and methods according to example embodiments of the inventive concept.

FIG. 13A is a schematic block diagram illustrating an example of an electronic system including a semiconductor device according to example embodiments of the inventive concept.

FIG. 13B is a schematic block diagram illustrating an example of a memory card including a semiconductor device according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like numbers indicate like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

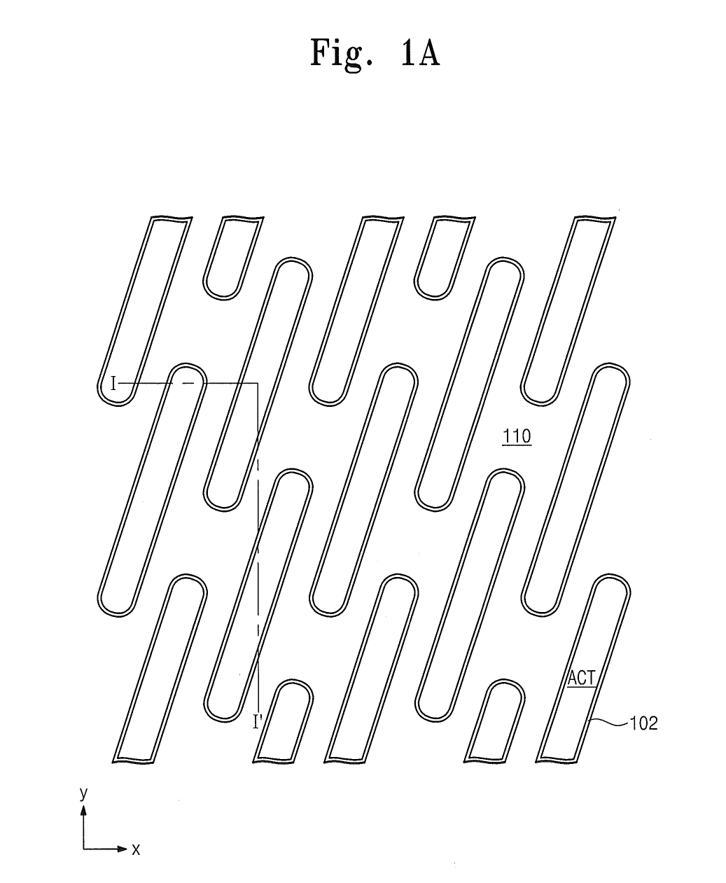

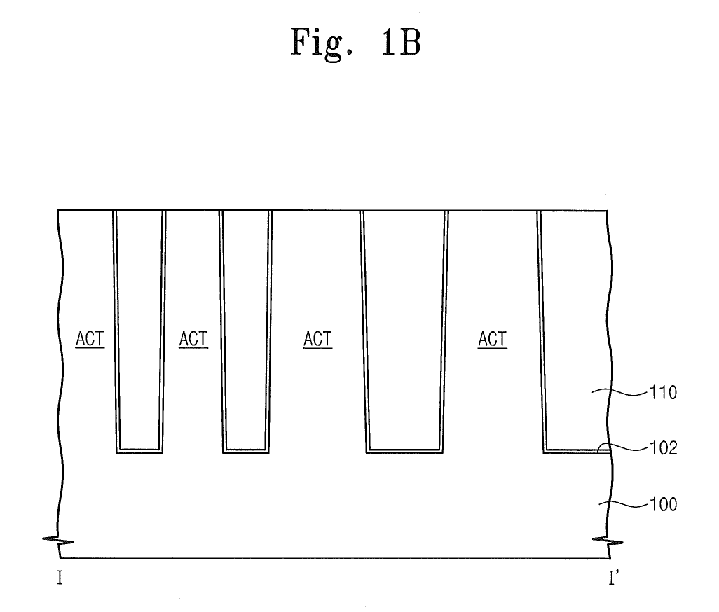

FIGS. 1A through 10B are plan and sectional views illustrating a semiconductor device according to example embodiments of the inventive concept. FIGS. 1B through 10B are sectional views taken along line I-I′ of FIGS. 1A through 10A, respectively.

Referring to FIGS. 1A and 1B, a device isolation pattern 110 may be formed in a substrate 100 to define active regions ACT.

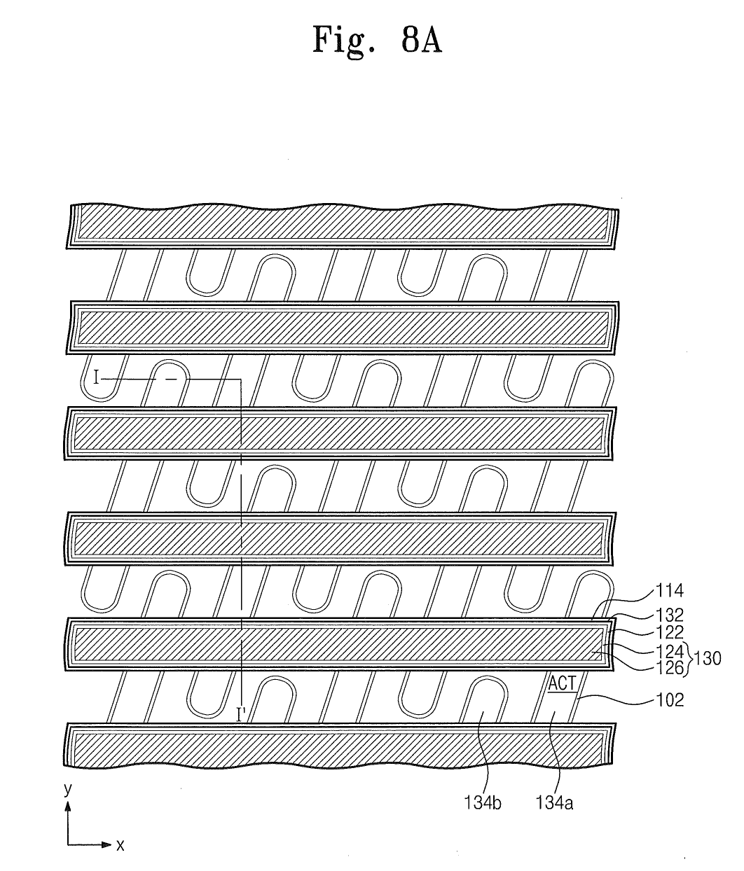

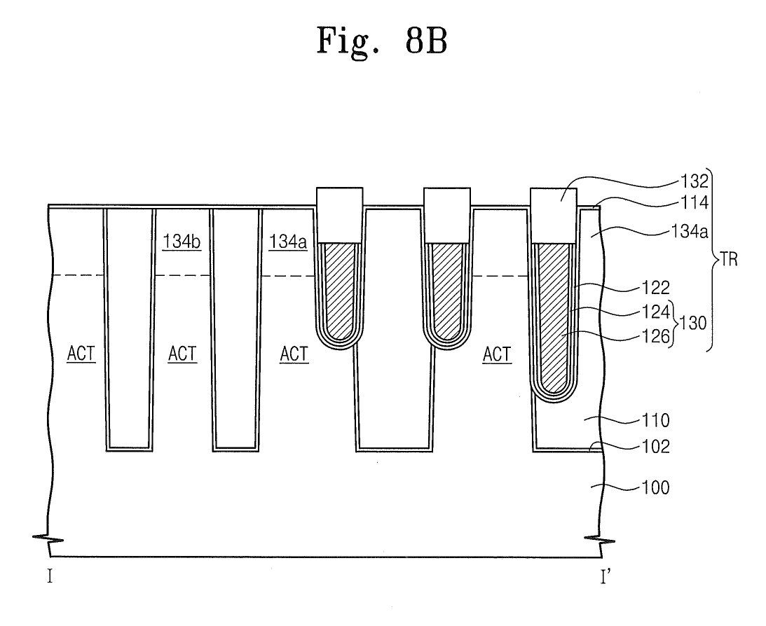

In example embodiments, the substrate 100 may be a silicon wafer, a germanium wafer, or a silicon-germanium wafer. The substrate 100 may be etched to form a trench. The trench may be filled with an insulating material to form the device isolation pattern 110. The insulating material may include at least one of oxide, nitride, or oxynitride. After the formation of the trench, a thin film 102 may be formed in the trench. The thin film 102 may prevent impurities in first and second doped regions 134a and 134b, which may be formed in subsequent steps (for example, of FIGS. 8A and 8B), from being diffused into the substrate 100. The thin film 102 may include at least one of nitride or oxynitride.

In plan view, the active regions ACT may be arranged spaced apart from each other to form a plurality of rows and a plurality of columns. The rows may be parallel to an x-axis direction, and the columns may be parallel to a y-axis direction. In example embodiments, the rows may include first, second and third rows that are adjacent to each other. Each of the active regions ACT constituting the first row may include a portion provided between a corresponding pair of the active regions ACT constituting the second row. Each of the active regions ACT constituting the third row may include a portion provided between a corresponding pair of the active regions ACT constituting the second row. The active regions ACT constituting the first to third rows may be spaced apart from each other. In plan view, each of the active regions ACT may have an elliptical or rectangular shape elongated along a specific direction. For example, a longitudinal axis of each active region ACT may be non-perpendicular and non-parallel to the x-axis direction.

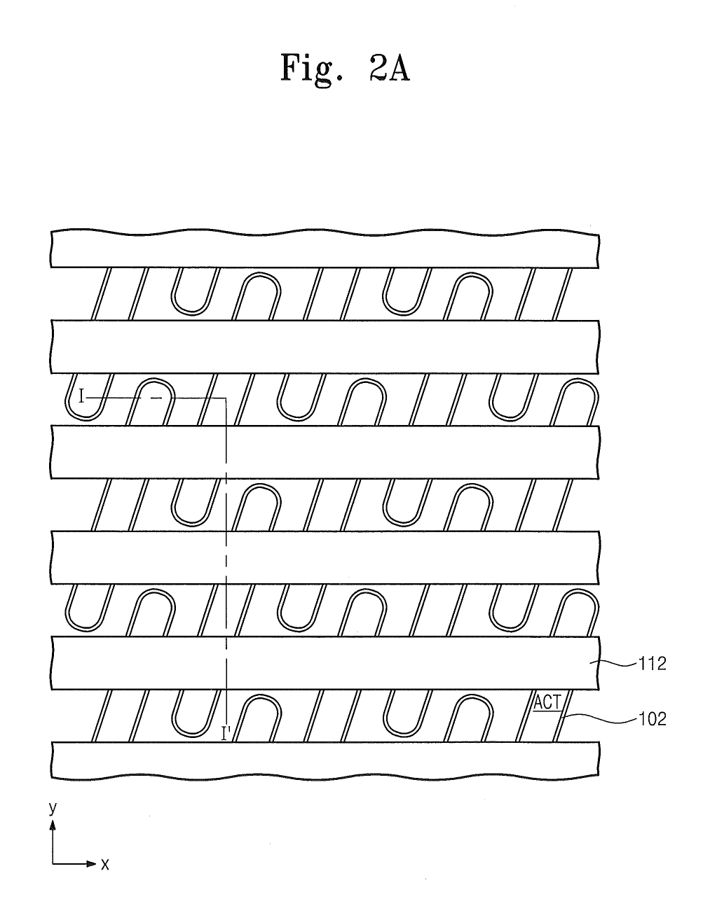

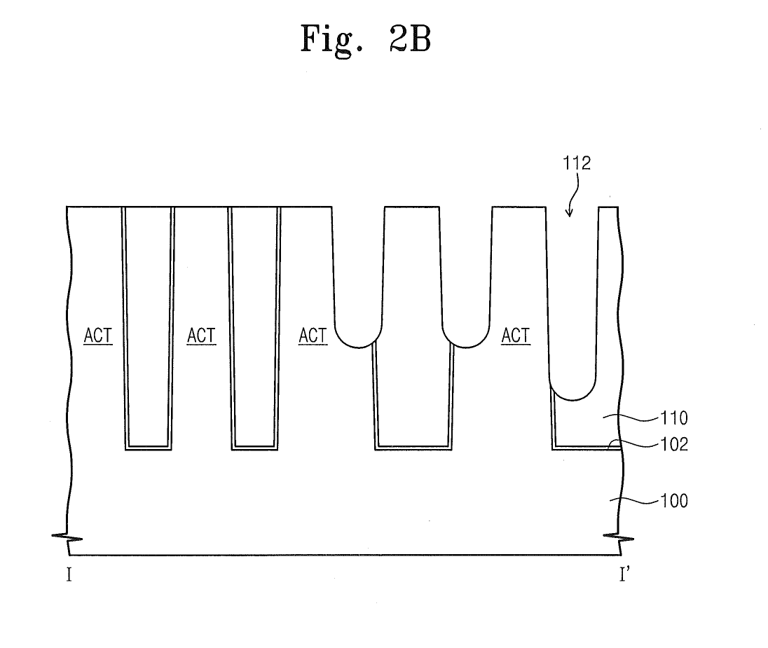

Referring to FIGS. 2A and 2B, recesses 112 may be formed in the substrate 100 with the active regions ACT and the device isolation pattern 110.

The recesses 112 may be formed to cross the active regions ACT and the device isolation pattern 110. The recesses 112 may be formed in a line shape parallel to the x-axis direction. In example embodiments, a depth of the recesses 112 may vary depending on position. For example, even in the same etching process, an etch rate of the device isolation pattern 110 may be higher than that of the substrate 100, due to a difference in material therebetween, and thus, a depth of the recess 112 may be deeper on the device isolation pattern 110 than on the active regions ACT. The recess 112 may be formed to have a bottom surface that is higher than that of the device isolation pattern 110.

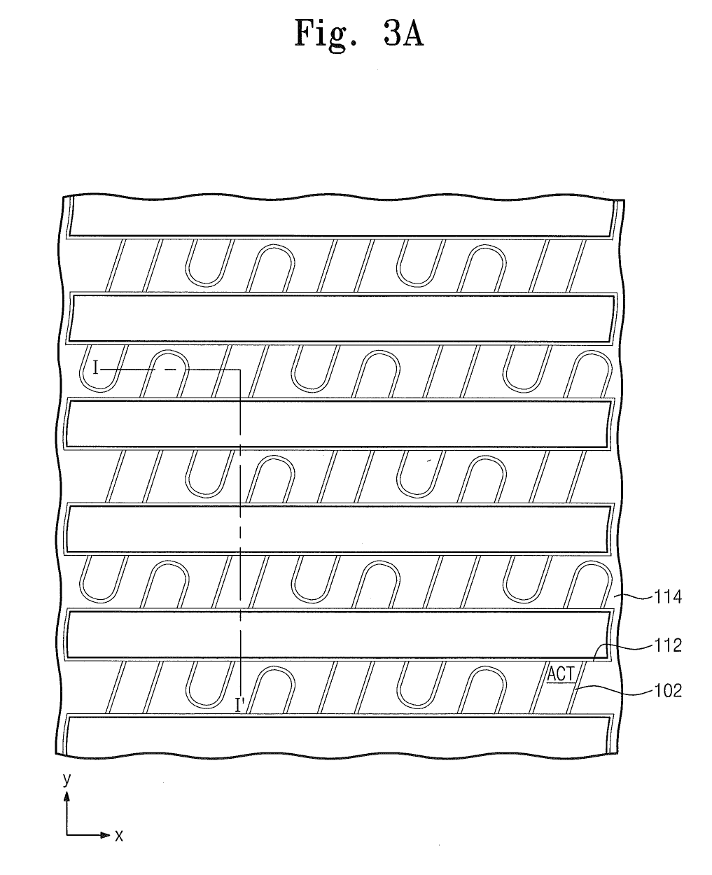

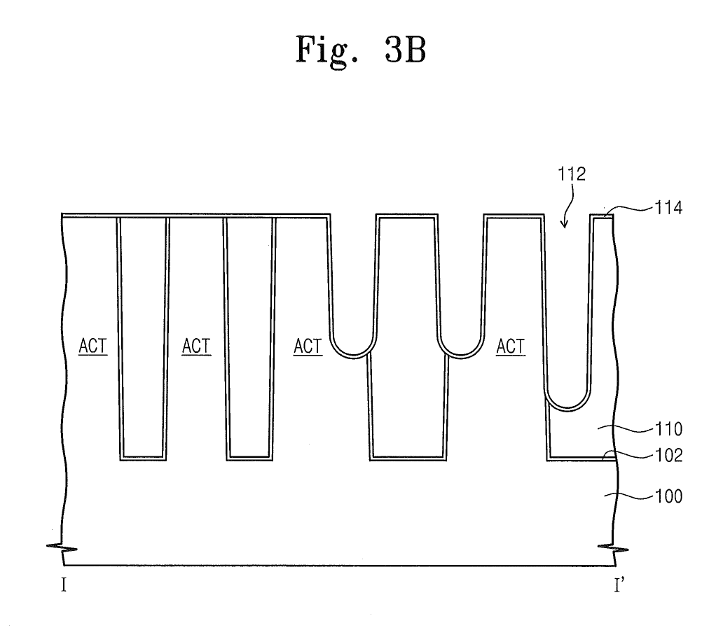

Referring to FIGS. 3A and 3B, a gate insulating layer 114 may be conformally formed on the substrate 100 provided with the recesses 112. The gate insulating layer 114 may be formed by a thermal oxidation or chemical vapor deposition process.

The gate insulating layer 114 may be formed of or include at least one of silicon oxide, silicon nitride, silicon oxynitride, or metal oxides (e.g., hafnium oxide and aluminum oxide).

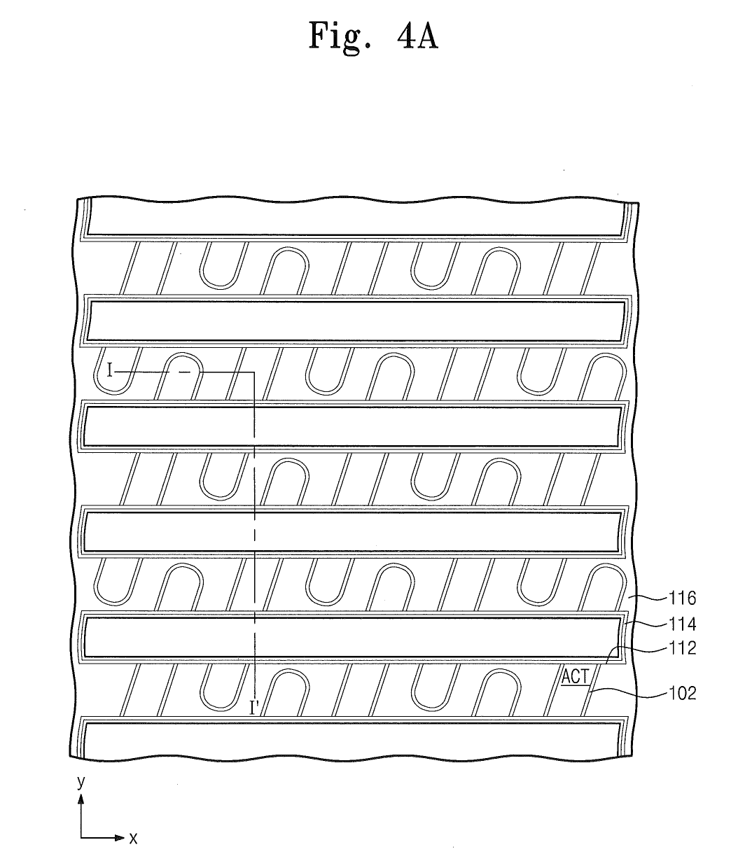

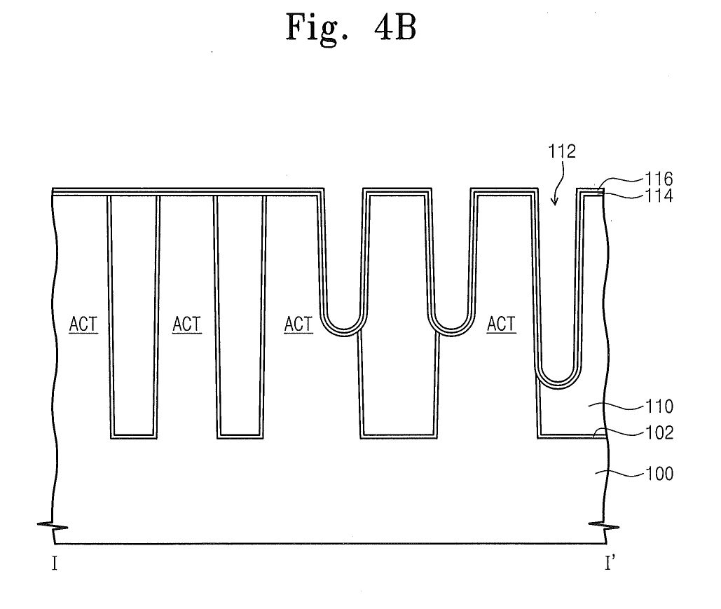

Referring to FIGS. 4A and 4B, a barrier layer 116 may be conformally formed on the gate insulating layer 114. The barrier layer 116 may prevent metallic element(s) in a gate electrode, which may be formed in the subsequent process, from being diffused into, for example, the active regions ACT. In example embodiments, the barrier layer 116 may include fluorine-free tungsten nitride.

In example embodiments, the barrier layer 116 may be formed by an atomic layer deposition process using a first precursor containing tungsten and a second precursor containing nitrogen. The first precursor may include bis(tert-butylimido)-bis-(dimethylamido)tungsten(VI) (BTBMW) and/or methylcyclopentadienyl-dicarbonylnitrosyl-tungsten (MDNOW). The second precursor may include ammonia (NH₃). The formation of the barrier layer 116 will be described in more detail below.

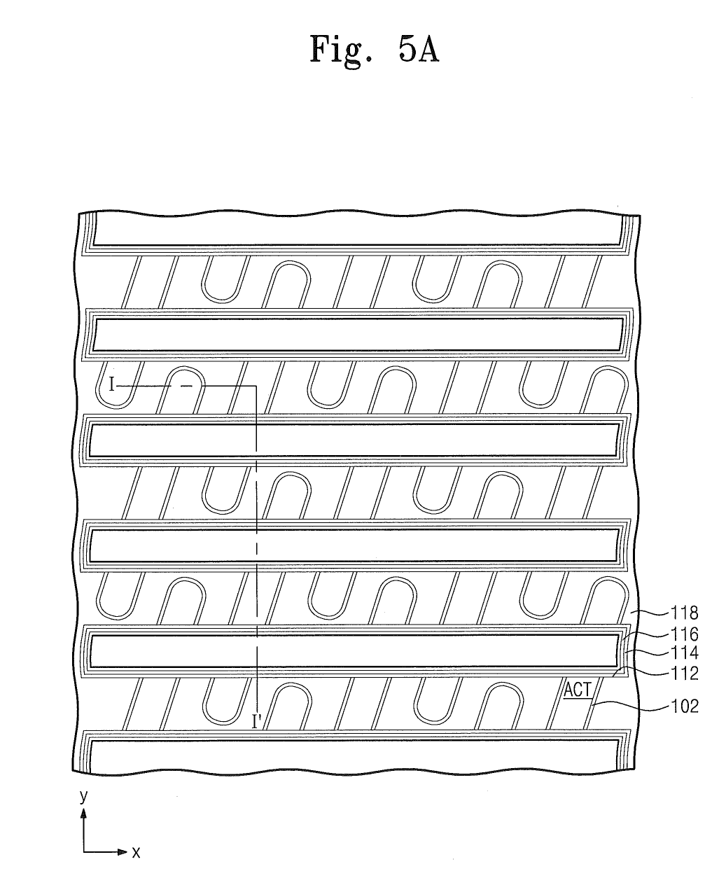

Referring to FIGS. 5A and 5B, a nucleation layer 118 may be conformally formed on the barrier layer 116. The nucleation layer 118 may be formed by an atomic layer deposition process using a first precursor containing tungsten and a second precursor containing boron. For example, the first precursor may include WF₆, and the second precursor may include B₂H₆. In example embodiments, the formation of the nucleation layer 118 may include at least one cycle consisting of steps of loading the substrate 100 with the barrier layer 116 in a process chamber, supplying a first precursor into the process chamber, firstly purging the process chamber, supplying the second precursor into the process chamber, and then, secondly purging the process chamber.

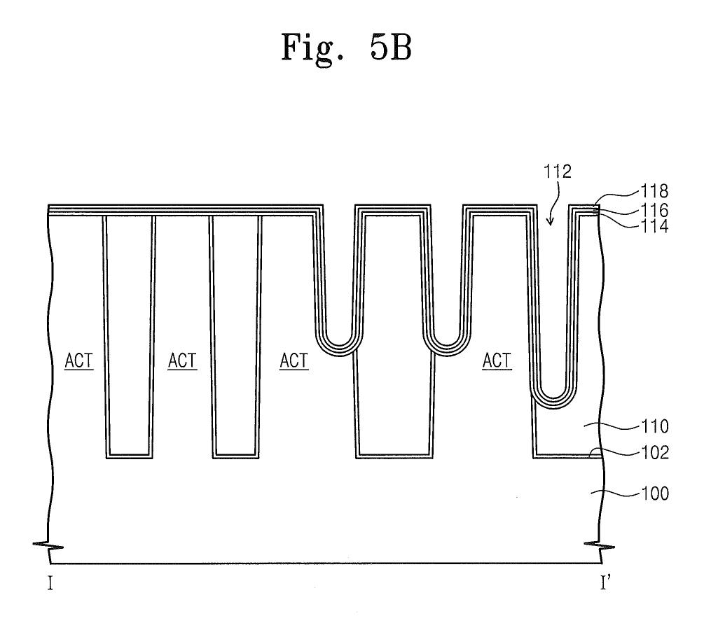

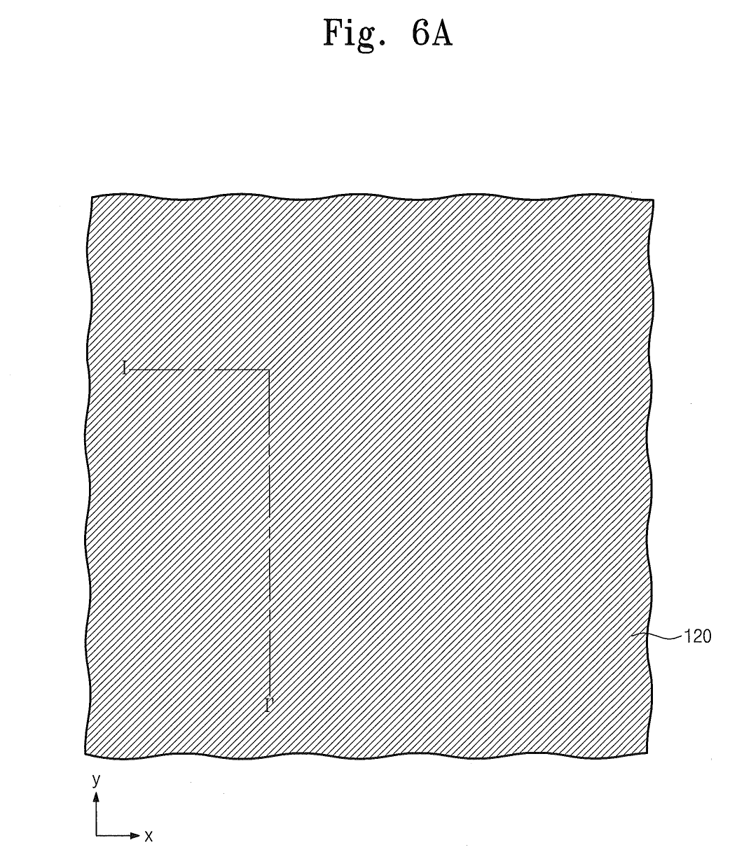

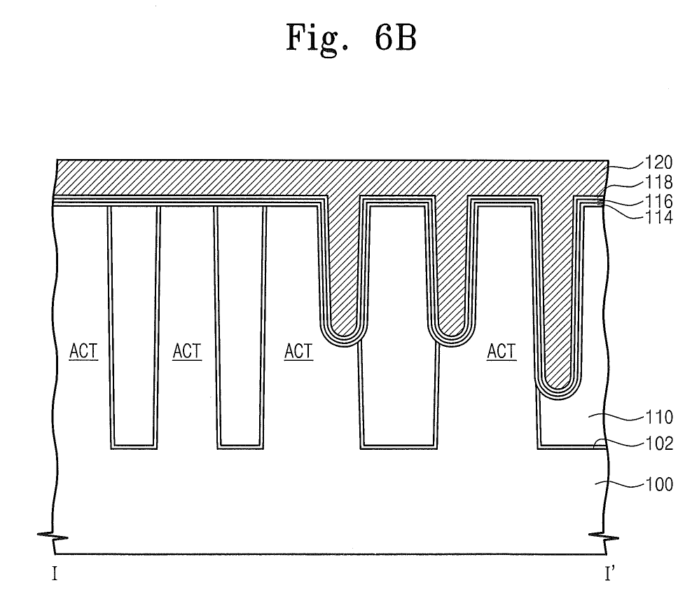

Referring to FIGS. 6A and 6B, a gate electrode layer 120 may be formed on the barrier layer 116 to fill the recess 112. The gate electrode layer 120 may be formed by a chemical vapor deposition process using the nucleation layer 118 and may include tungsten.

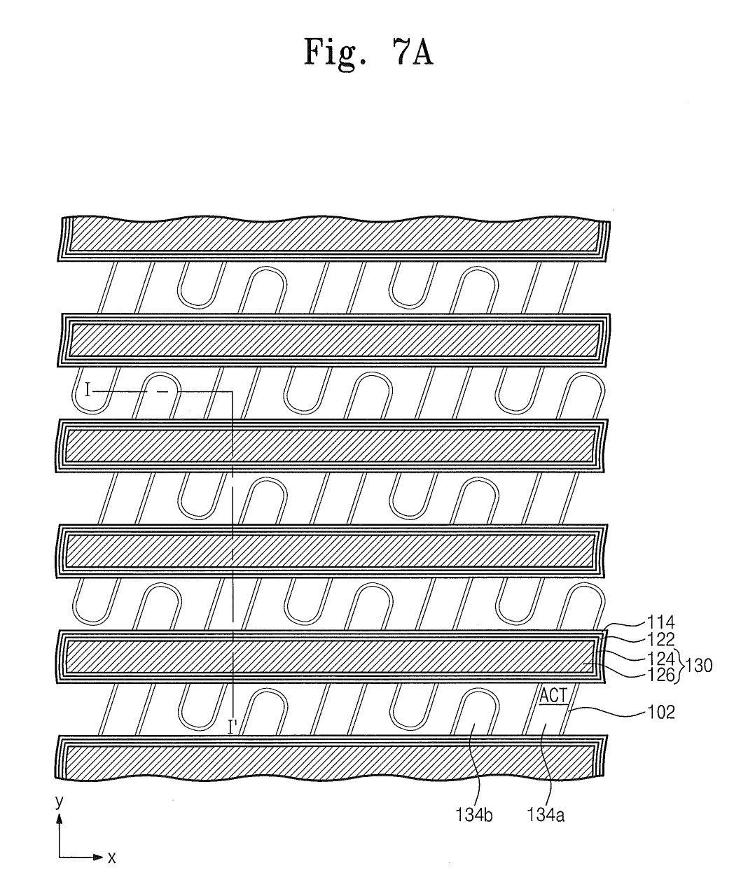

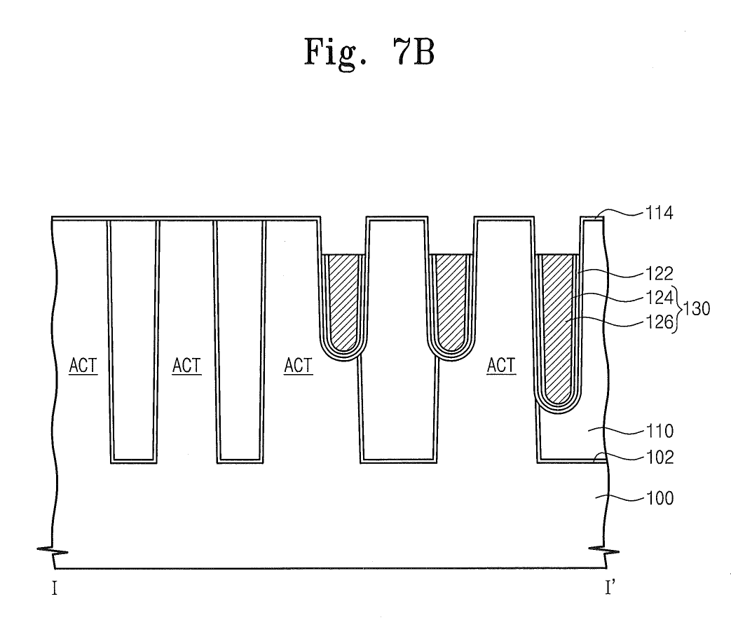

Referring to FIGS. 7A and 7B, the gate electrode layer 120 and the barrier layer 116 may be etched to expose an upper side surface of each of the recesses 112 and thereby form barrier patterns 122 and gate electrodes 130.

During the etching process, the gate electrode layer 120 and the nucleation layer 118 may be etched to form gate electrode patterns 126 and nucleation patterns 124 constituting the gate electrodes 130.

Each of the gate electrodes 130 may be formed to fill a lower region of a corresponding one of the recesses 112. In plan view, the gate electrodes 130 may be formed to cross the active regions ACT. The gate electrodes 130 may be elongate parallel to the x-axis direction and arranged spaced apart from each other in the y-axis direction.

Referring to FIGS. 8A and 8B, impurities may be injected into portions of the active regions ACT at both sides of the gate electrode 130 to form first and second doped regions 134a and 134b. The first and second doped regions 134a and 134b may serve as source and/or drain regions.

Masks 132 may be formed on the gate electrode 130. The masks 132 may be elongate and parallel to the x-axis direction and disposed spaced apart from each other in the y-axis direction.

The gate insulating layer 114, the barrier layer 116 (or barrier patterns 122), the gate electrode 130, the mask 132, the first and second doped regions 134a and 134b may constitute a transistor TR integrated on the substrate 100. According to the present embodiment, a portion of the substrate 100 spaced apart from a top surface thereof may be used as a channel region of the transistor TR. For example, the transistor TR may be provided in the form of a barrier channel array transistor (BCAT).

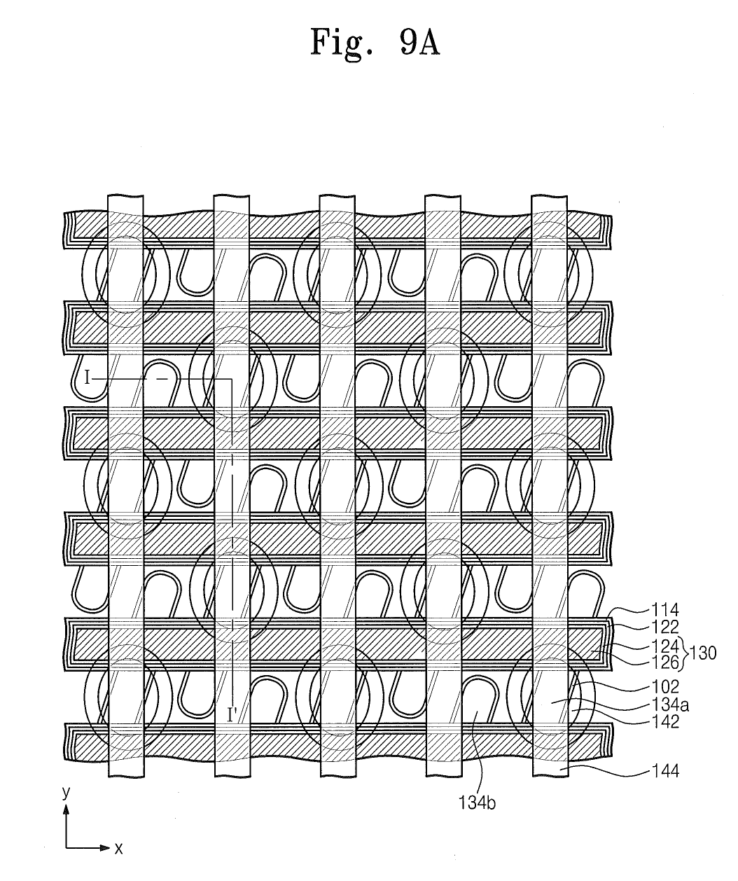

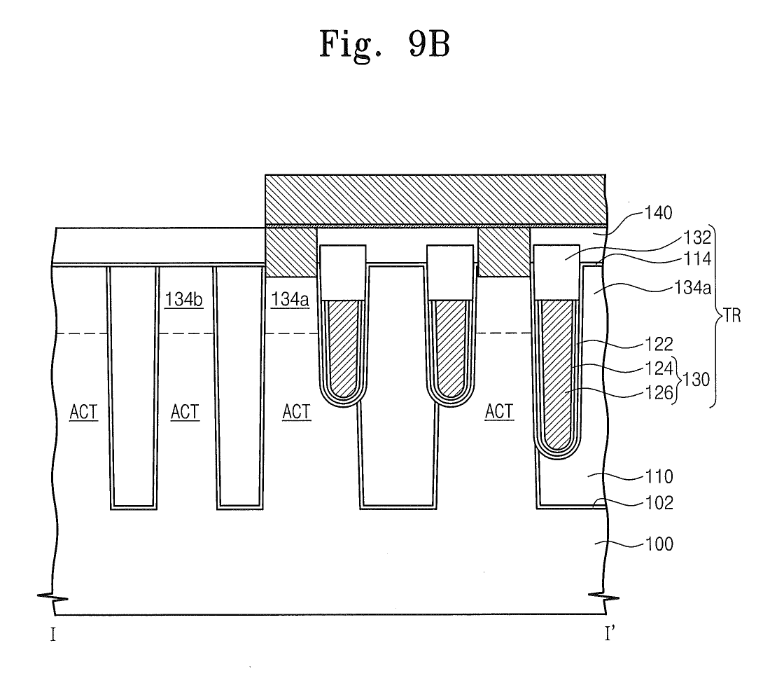

Referring to FIGS. 9A and 9B, a bit line 144 may be formed to be electrically connected to the first doped region 134a.

For example, a first interlayered insulating layer 140 may be formed on the substrate 100 provided with the transistors TR. The first interlayered insulating layer 140 may be etched to form an opening exposing the first doped region 134a, and a first contact plug 142 may be formed in the opening and be electrically connected to the first doped region 134a. The bit line 144 may be formed on the first interlayered insulating layer 140 to extend parallel to the y-axis direction. The bit line 144 may be electrically connected to the first contact plug 142. Accordingly, the bit line 144 may be electrically connected to the first doped region 134a through the first contact plug 142.

Although not shown in detail, the substrate 100 may include a cell region for memory cells and a peripheral region for logic circuits. When the bit line 144 is formed on the cell region, a peripheral gate electrode may be formed on the peripheral region of the substrate 100.

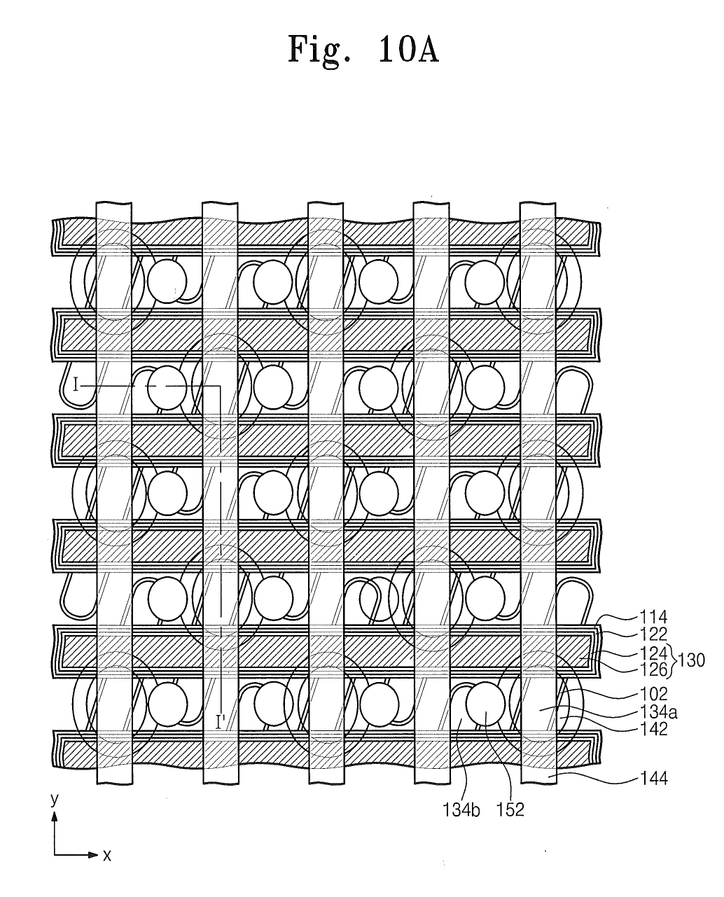

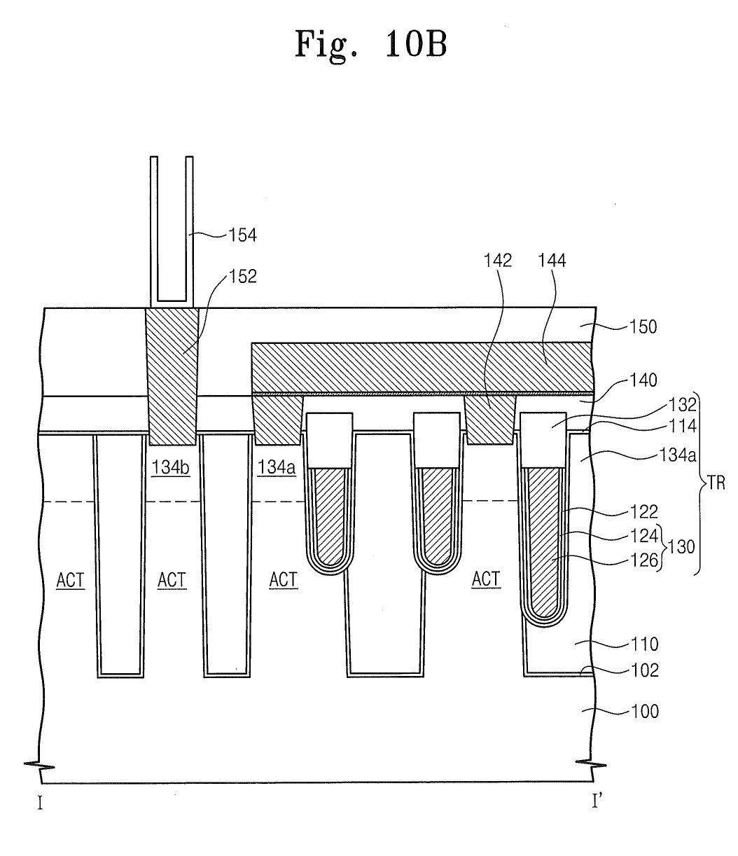

Referring to FIGS. 10A and 10B, a capacitor may be formed to be electrically connected to the second doped region 134b.

For example, a second interlayered insulating layer 150 may be formed on the first interlayered insulating layer 140 and the bit line 144. The first and second interlayered insulating layers 140 and 150 may be etched to form an opening exposing the second doped region 134b, and then, a second contact plug 152 may be formed in the opening and be electrically connected to the second doped region 134b. The capacitor may be formed on the second interlayered insulating layer 150 and be electrically connected to the second contact plug 152. In other words, the capacitor may be electrically connected to the second doped region 134b through the second contact plug 152. The capacitor may include a lower electrode 154, which is shaped like, for example, a top-open and bottom-closed cylinder or a cup.

Hereinafter, a process of forming the barrier layer will be described in more detail.

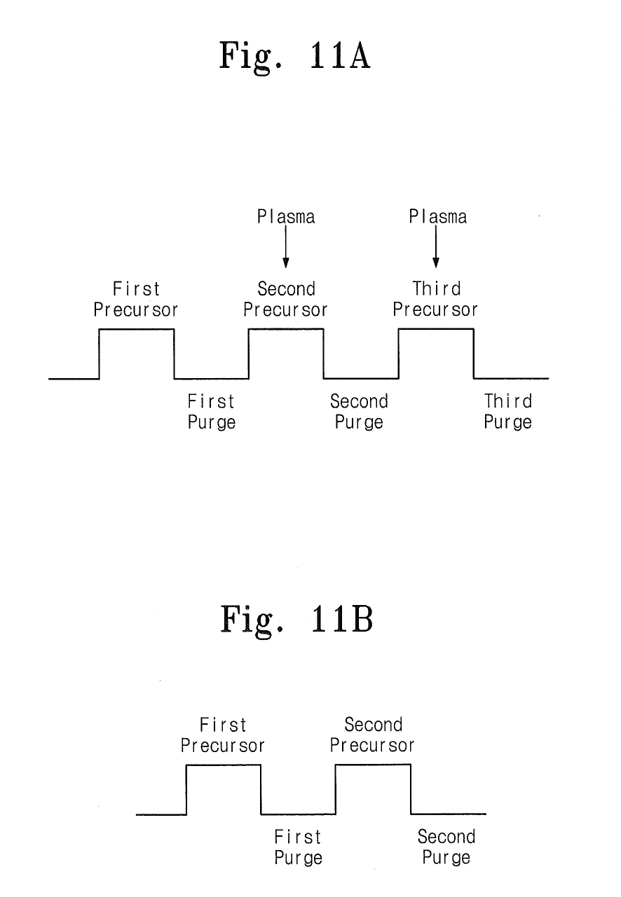

FIG. 11A is a process cycle illustrating a process of forming a barrier layer according to example embodiments of the inventive concept.

Referring to FIG. 11A, the barrier layer may be formed by a plasma-enhanced atomic layer deposition process, in which three precursors are used.

For example, the barrier layer may be formed by a plasma-enhanced atomic layer deposition process, in which a first precursor containing tungsten, a second precursor containing nitrogen, and a third precursor containing hydrogen are used. In more detail, the substrate 100 with the gate insulating layer may be loaded in a process chamber, and the first precursor may be supplied into the process chamber. The first precursor may include, for example, methylcyclopentadienyl-dicarbonylnitrosyl-tungsten (MDNOW). Thereafter, a first purge process may be performed to the process chamber. The second precursor may be supplied into the process chamber, in which plasma is produced. The second precursor may include, for example, ammonia (NH₃). A second purge process may be performed to the process chamber, and the third precursor may be supplied into the process chamber, in which plasma is produced. The third precursor may include, for example, hydrogen (H₂).

In other embodiments, the barrier layer may be formed by a plasma-enhanced atomic layer deposition process, in which a first precursor containing tungsten, a second precursor containing hydrogen, and a third precursor containing nitrogen are used. In detail, the substrate 100 with the gate insulating layer may be loaded in a process chamber, and the first precursor may be supplied into the process chamber. The first precursor may include, for example, methylcyclopentadienyl-dicarbonylnitorsyl-tungsten (MDNOW). Thereafter, a first purge process may be performed to the process chamber. The second precursor may be supplied into the process chamber, in which plasma is produced. For example, the second precursor may include hydrogen (H₂). A second purge process may be performed to the process chamber, and the third precursor may be supplied into the process chamber, in which plasma is produced. For example, the third precursor may include ammonia (NH₃).

The plasma-enhanced atomic layer deposition process may be performed under plasma with power ranging from about 250 W to about 350 W, at a temperature ranging from about 100° C. to about 200° C.

The process of forming the barrier layer on the gate insulating layer may include performing several times the process cycle consisting of the first precursor supply, the first purge, the second precursor supply under plasma, the second purge, the third precursor supply under plasma, and the third purge.

Since the barrier layer is formed using fluorine-free precursors, it is possible to prevent the gate insulating layer from being damaged by fluorine. Further, according to the above process, the barrier layer may be formed of a tungsten nitride layer, which has an electric resistance that is lower than that of the conventional barrier layer (e.g., made of titanium nitride (TiN)). This will be described in more detail below.

FIG. 11B is a process cycle illustrating a process of forming a barrier layer according to other example embodiments of the inventive concept.

Referring to FIG. 11B, the barrier layer may be formed by a thermal atomic layer deposition process, in which a first precursor containing tungsten and a second precursor containing nitrogen are used. The thermal atomic layer deposition may be performed at a temperature ranging from about 300° C. to about 500° C.

In more detail, the substrate 100 provided with the gate insulating layer may be loaded in a process chamber, and then, the first precursor may be supplied into the process chamber. The first precursor may include, for example, bis (tert-butylimido)-bis-(dimethylamido)tungsten (VI) (BTBMW). Thereafter, a first purge may be performed to the process chamber. The second precursor may be supplied into the process chamber. The second precursor may include, for example, ammonia (NH₃). Next, a second purge may be performed to the process chamber. By performing several times a process cycle consisting of the first precursor supply, the first purge, the second precursor supply, and the second purge, it is possible to form the barrier layer on the gate insulating layer.

According to the above process, the barrier layer may be formed using fluorine-free precursors, and thus, it is possible to prevent the gate insulating layer from being damaged by fluorine. Further, according to the above process, the barrier layer may be formed of a tungsten nitride layer, which has an electric resistance that is lower than that of the conventional barrier layer (e.g., made of titanium nitride (TiN)).

Table 1 shows content ratios of tungsten, nitrogen, and carbon contained in barrier layers that were formed using the processes of FIGS. 11A and 11B.

TABLE 1

| The barrier layer of FIG. 11A | | | The barrier layer of FIG. 11B | | |
|---|---|---|---|---|---|
| tungsten | | | tungsten | | |
| (W) | nitrogen (N) | carbon (C) | (W) | nitrogen (N) | carbon (C) |
| 58% | 37% | 4% | 45% | 37% | 15% |

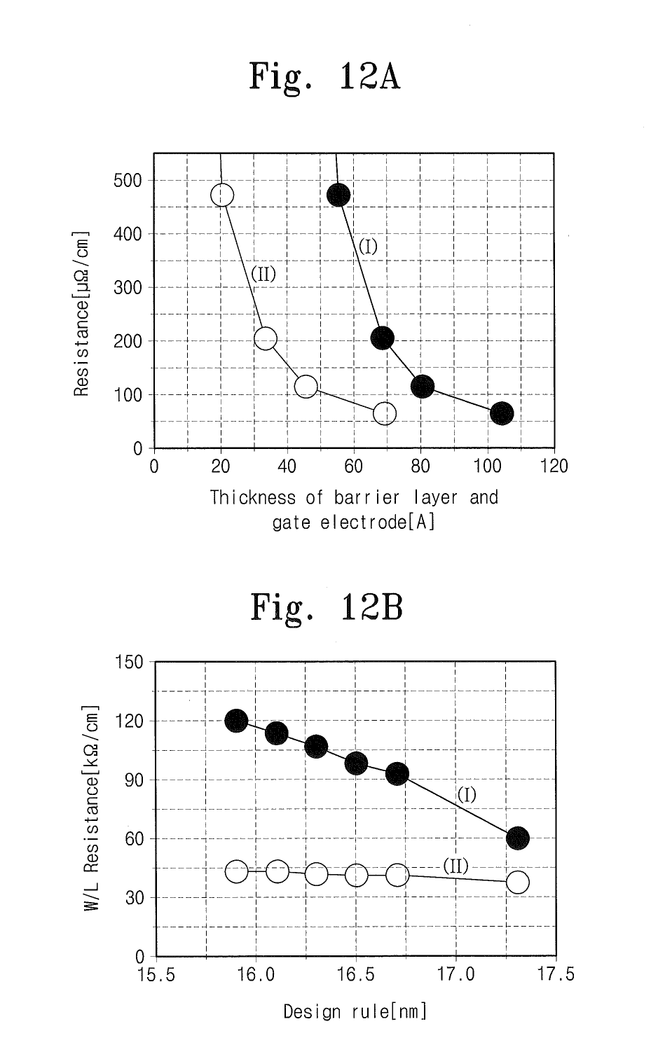

FIG. 12A is a graph showing a relationship between resistance and thickness of barrier layers and gate electrodes that were formed by the conventional processes and the above described process.

The barrier layer and the gate electrode formed by the conventional process contained titanium nitride and tungsten, respectively, and a relationship between resistance and thickness thereof is depicted by a curve (I) in FIG. 12A. According to the process described with reference to FIG. 11B, the barrier layer and the gate electrode were formed to contain tungsten nitride and tungsten, respectively, and a relationship between resistance and thickness thereof is depicted by a curve (II) in FIG. 12A.

Referring to FIG. 12A, in both of the conventional and above-described processes, the lower the thickness of the barrier layer and the gate electrode, the higher the resistance thereof. The resistance of the barrier layer and the gate electrode was lower for the above-described process than for the conventional process. For example, for the conventional process, the resistance was about 200 μohm/cm, at the thickness of about 70 Å, while, for the above-described process, the resistance was about 50 μohm/cm, at the thickness of about 70 Å.

This shows that if the barrier layer containing tungsten nitride is used, it is possible to reduce resistance of the barrier layer and the gate electrode and improve reliability of the transistor, compared with the conventional case.

FIG. 12B is a graph showing a relationship between resistance and design rule of barrier layers and gate electrodes that were formed by a conventional process and the above described process.

The barrier layer and the gate electrode formed by the conventional process contained titanium nitride and tungsten, respectively, and a relationship between resistance and design rule thereof is depicted by a curve (I) in FIG. 12B. According to the process described with reference to FIG. 11B, the barrier layer and the gate electrode were formed to contain tungsten nitride and tungsten, respectively, and a relationship between resistance and design rule thereof is depicted by a curve (II) in FIG. 12B.

Referring to FIG. 12B, in both of the conventional and above-described processes, the smaller the design rule of the barrier layer and the gate electrode, the higher the resistance thereof. When the design rule decreases, a rate of increase in resistance was much higher for the conventional process than for the above-described process.

This shows that if the barrier layer containing tungsten nitride is used, it is possible to reduce resistance of the barrier layer and the gate electrode and improve reliability of the transistor, compared with the conventional case.

So far, some embodiments applicable to semiconductor memory devices were described, but example embodiments of the inventive concepts may not be limited thereto. For example, the above-described technical features of the semiconductor devices, according to example embodiments of the inventive concept, can be applied to realize non-memory devices (e.g., logic devices).

The semiconductor devices disclosed above may be encapsulated using various and diverse packaging techniques. For example, the semiconductor devices according to the aforementioned embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline integrated circuit (SOIC) technique, a shrink small outline package (SSOP) technique, a thin small outline package (TSOP) technique, a system in package (SIP) technique, a multi-chip package (MCP) technique, a wafer-level fabricated package (WFP) technique and a wafer-level processed stack package (WSP) technique. The package in which the semiconductor device according to one of the above embodiments is mounted may further include at least one semiconductor device (e.g., a controller and/or a logic device) that controls the semiconductor device.

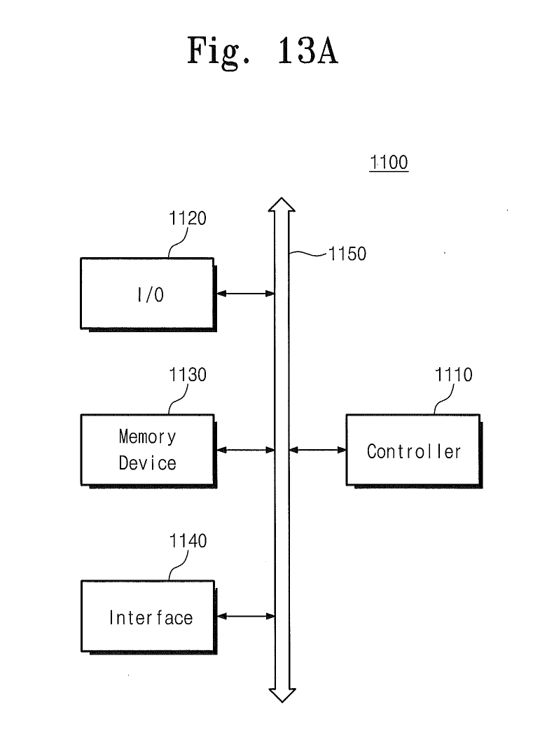

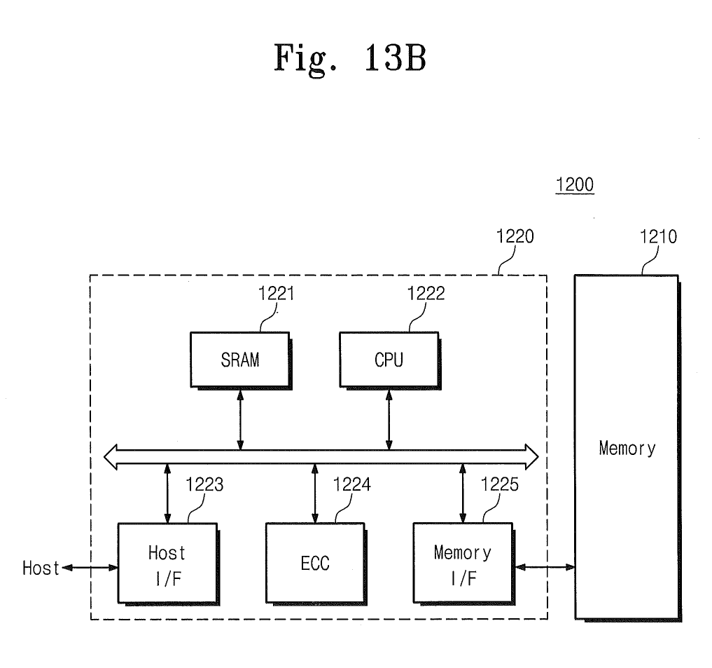

FIG. 13A is a schematic block diagram illustrating an example of an electronic system including a semiconductor device according to example embodiments of the inventive concept.

Referring to FIG. 13A, an electronic system 1100 according to example embodiments may include a controller 1110, an input/output (I/O) unit 1120, a memory device 1130, an interface unit 1140 and a bus 1150. At least two of the controller 1110, the I/O unit 1120, the memory device 1130 and the interface unit 1140 may communicate with each other through the bus 1150. The bus 1150 may correspond to a path through which electrical signals are transmitted.

The controller 1110 may include at least one of a microprocessor, a digital signal processor, a microcontroller or another logic device. The other logic device may have a similar function to any one of the microprocessor, the digital signal processor and the microcontroller. The I/O unit 1120 may include a keypad, a keyboard or a display unit. The memory device 1130 may store data and/or commands. The memory device 1130 may include at least one of the semiconductor devices according to the afore-described embodiments. The interface unit 1140 may transmit electrical data to a communication network or may receive electrical data from a communication network. The interface unit 1140 may operate by cable or wirelessly. For example, the interface unit 1140 may include an antenna for wireless communication or a transceiver for cable communication. Although not shown in the drawings, the electronic system 1100 may further include a fast DRAM or SRAM device that acts as a cache memory for improving an operation of the controller 1110.

The electronic system 1100 may be applied to a personal digital assistant (PDA), a portable computer, a web tablet, a wireless phone, a mobile phone, a digital music player, a memory card or an electronic product. The electronic product may wirelessly receive or transmit information data.

FIG. 13B is a schematic block diagram illustrating an example of a memory card including a semiconductor device according to example embodiments of the inventive concept.

Referring to FIG. 13B, a memory card 1200 according to example embodiments of the inventive concept may include a memory device 1210. The memory device 1210 may include at least one of the semiconductor devices according to the afore-described embodiments. The memory card 1200 may include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as an operation memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. Even though not shown in the drawings, the memory card 1200 may further include a read only memory (ROM) device that stores code data to interface with the host. The memory card 1200 may be used as a portable data storage card. Alternatively, the memory card 1200 may replace hard disks of computer systems as solid state disks (SSD) of the computer systems.

According to example embodiments of the inventive concept, a barrier layer including fluorine-free tungsten nitride may be formed using an atomic layer deposition process, and this makes it possible to decrease electric resistances of the barrier layer and the gate electrode.

While example embodiments of the inventive concepts have been particularly shown and described, it will be understood by one of ordinary skill in the art that variations in form and detail may be made therein without departing from the spirit and scope of the attached claims.

What is claimed is:

1. A method of fabricating a semiconductor device, the method comprising:
conformally forming a gate insulating layer on a substrate having a recess;
conformally forming a barrier layer containing fluorine-free tungsten nitride on the substrate with the gate insulating layer using an atomic layer deposition process; and
forming a gate electrode on the barrier layer to fill at least a portion of the recess.

2. The method of claim 1, wherein the forming of the barrier layer comprises:
loading the substrate with the gate insulating layer into a process chamber;
supplying a first precursor containing tungsten into the process chamber; and
supplying a second precursor containing nitrogen into the process chamber.

3. The method of claim 2, wherein the first precursor contains bis(tert-butylimido)-bis-(dimethylamido)tungsten(VI) (BTBMW) or methylcyclopentadienyl-dicarbonylnitrosyl-tungsten (MDNOW).

4. The method of claim 2, wherein the second precursor contains ammonia (NH₃).

5. The method of claim 2, further comprising:
firstly purging the process chamber, after the supplying of the first precursor; and
secondly purging the process chamber, after the supplying of the second precursor.

6. The method of claim 1, wherein the atomic layer deposition process is performed using a plasma-enhanced atomic layer deposition process.

7. The method of claim 6, wherein the plasma-enhanced atomic layer deposition process comprises:
loading the substrate with the gate insulating layer in a process chamber;
supplying a precursor of methylcyclopentadienyl-dicarbonylnitrosyl-tungsten (MDNOW) into the process chamber;
firstly purging the process chamber;
supplying a precursor of ammonia (NH₃) into the process chamber, in which plasma is produced;
secondly purging the process chamber;
supplying a precursor of hydrogen (H₂) into the process chamber, in which plasma is produced; and
thirdly purging the process chamber.

8. The method of claim 6, wherein the plasma-enhanced atomic layer deposition process comprises:
loading the substrate with the gate insulating layer in a process chamber;
supplying a precursor of methylcyclopentadienyl-dicarbonylnitrosyl-tungsten (MDNOW) into the process chamber;
firstly purging the process chamber;
supplying a precursor of hydrogen (H₂) into the process chamber, in which plasma is produced;
secondly purging the process chamber;
supplying a precursor of ammonia (NH₃) into the process chamber, in which plasma is produced; and
thirdly purging the process chamber.

9. The method of claim 6, wherein the plasma-enhanced atomic layer deposition process is performed under plasma with power ranging from about 250 W to about 350 W and at a temperature ranging from about 100° C. to about 200° C.

10. The method of claim 1, wherein the atomic layer deposition process is performed using a thermal atomic layer deposition process.

11. The method of claim 10, wherein the thermal atomic layer deposition process comprises:
loading the substrate with the gate insulating layer in a process chamber heated to a temperature ranging from 300° C. to 500° C.;
supplying a precursor of bis(tert-butylimido)-bis-(dimethylamido)tungsten (VI) (BTBMW) into the process chamber;
firstly purging the process chamber;
supplying a precursor of ammonia (NH₃) into the process chamber; and
secondly purging the process chamber.

12. The method of claim 1, wherein the gate electrode is formed to contain tungsten.

13. The method of claim 12, wherein the forming of the gate electrode comprises:
conformally forming a nucleation layer on the barrier layer;
forming a tungsten layer to fill the recess provided with the nucleation layer using a chemical vapor deposition process; and
etching the tungsten layer, the nucleation layer, and the barrier layer to expose the gate insulating layer through an upper side surface of the recess.

14. The method of claim 12, wherein the forming of the nucleation layer comprises:
loading the substrate provided with the barrier layer in a process chamber;
supplying a first precursor containing tungsten into the process chamber; and
supplying a second precursor containing boron into the process chamber.

15. The method of claim 14, wherein the first precursor contains WF₆ and the second precursor contains B₂H₆.

16. A method of fabricating a semiconductor device, the method comprising:
conformally forming a gate insulating layer on a substrate having a recess;
conformally forming a barrier layer containing fluorine-free tungsten nitride on the substrate with the gate insulating layer using an atomic layer deposition process, wherein the forming the barrier layer comprises:
loading the substrate with the gate insulating layer into a process chamber;
supplying a first precursor containing tungsten into the process chamber; then
purging the process chamber a first time; then
supplying a second precursor containing nitrogen into the process chamber; and then
purging the process chamber a second time; and
forming a gate electrode on the barrier layer to fill at least a portion of the recess.

17. The method of claim 16, wherein the first precursor contains bis(tert-butylimido)-bis-(dimethylamido)tungsten(VI) (BTBMW) or methylcyclopentadienyl-dicarbonylnitrosyl-tungsten (MDNOW).

18. The method of claim 16, wherein the second precursor contains ammonia (NH₃).

19. A method of fabricating a semiconductor device, the method comprising:
conformally forming a gate insulating layer on a substrate having a recess;
conformally forming a barrier layer containing fluorine-free tungsten nitride on the substrate with the gate insulating layer using a plasma-enhanced atomic layer deposition process, wherein the plasma-enhanced atomic layer deposition process is performed under plasma with power ranging from about 250 W to about 350 W and at a temperature ranging from about 100° C. to about 200° C.; and
forming a gate electrode on the barrier layer to fill at least a portion of the recess.

20. The method of claim 19, wherein the plasma-enhanced atomic layer deposition process comprises:
loading the substrate with the gate insulating layer in a process chamber; then
supplying a precursor of methylcyclopentadienyl-dicarbonylnitrosyl-tungsten (MDNOW) into the process chamber; then
purging the process chamber a first time; then
supplying a precursor of one of ammonia (NH₃) and hydrogen (H₂) into the process chamber; then
purging the process chamber a second time; then
supplying a precursor of the other one of ammonia (NH₃) and hydrogen (H₂) into the process chamber; and then
purging the process chamber a third time.
